(19) United States
(12) Patent Application Publication
(10) Pub. No.: US 2009/0197388 A1
(43) Pub. Date: Aug. 6, 2009

(54) METHOD OF MANUFACTURING SEMICONDUCTOR DEVICE

(76) Inventor: Min-Gon Lee, Gyeongsangnam-do (KR)

Correspondence Address: SHERR & VAUGHN, PLLC, 620 HERNDON PARKWAY, SUITE 200, HERNDON, VA, 20170, US

(21) Appl. No.: 11/869,452

(22) Filed: Oct. 9, 2007

(30) Foreign Application Priority Data
Oct. 11, 2006 (KR) 10-2006-0098759

(51) Int. Cl. H01L 21/762

(52) U.S. Cl. 438/424; 257/E21.546

(57) ABSTRACT

A method of manufacturing a semiconductor device including at leasty one of the following steps: sequentially forming a first oxide layer, a nitride layer, a second oxide layer, a bottom anti-reflect coating and a photo-resist pattern over a semiconductor substrate; exposing the uppermost surface of the semiconductor substrate by performing a first reactive ion etch process; and then forming a trench in the uppermost surface of the semiconductor substrate by performing a second reactive ion etch process.

The present application claims priority under 35 U.S.C. 119 to Korean Patent Application No. 10-2006-0098759 (filed on Oct. 11, 2006), which is hereby incorporated by reference in its entirety.

### BACKGROUND

Aspects of semiconductor technology have focused on highly integrated devices and the insulation of device isolating techniques. Device isolating techniques may include a local oxidation of silicon (LOCOS) method that forms a device isolating layer by selectively growing an oxide film on and/or over the semiconductor substrate. However, a shortcoming in the LOCOS method is the reduction in width of the device isolating layer.

Accordingly, shallow trench isolation (STI) has been employed in order to form device isolating layers. The STI process includes the formation of a trench on and/or over the semiconductor substrate and burying the inside of the trench with an insulating layer. The STI process has excellent device isolating characteristics and a small occupying area as compared to other techniques for forming a device isolating layer.

The STI process may require use of a three-step dry etch process, which may include an active reactive ion etch (AA RIE) process forming an active part with which a gate of a device may be provided, an AA spacer RIE process performing an etch using the spacer, and an AA SI RIE process forming the trench by etching the silicon substrate.

In applying a design rule of 90 nm to the dry etch process for forming the STI, in order to optimize the processes, the AA RIE, the AA spacer RIE, and the AA SI RIE processes are sequentially progressed based on a 130 nm foundry compatible technology (FCT).

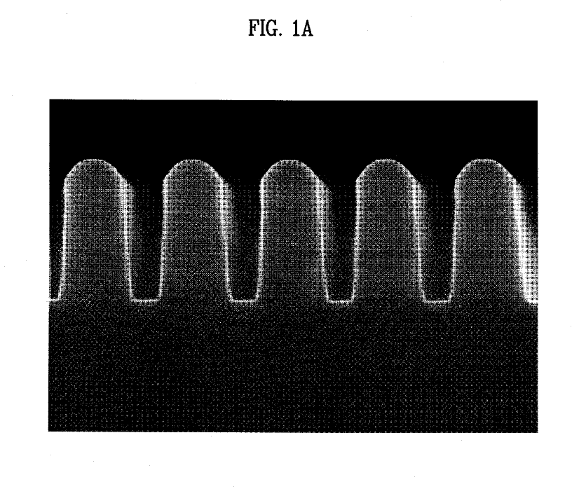

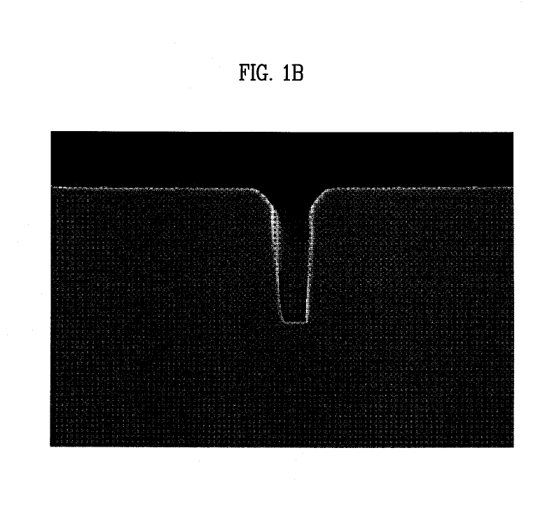

A condition applied to the design rule of 130 nm may be applied to the design rule of 90 nm to perform the etching. Then, the thickness of tetra ethyl ortho silicate (TEOS) remaining after performing the AA RIE may be too thin. As illustrated in example FIGS. 1A and 1B, when etching a semiconductor in order to form an STI, the thin TEOS layer can pose a problem during processing.

### SUMMARY

Embodiments relate to a method of manufacturing a semiconductor device capable of achieving the optimization of a STI process according to a design rule of 90 nm.

Embodiments relate to a method of manufacturing a semiconductor device including at least one of the following steps: sequentially forming a first oxide layer, a nitride layer, a second oxide layer, a bottom anti-reflect coating (BARC), and a photo-resist pattern on and/or over a semiconductor substrate; exposing the semiconductor substrate by performing a first reactive ion etch (RIE) on and/or over the semiconductor substrate; and forming a trench by performing a second RIE process on and/or over the exposed semiconductor substrate.

### DRAWINGS

Example FIGS. 1A and 1B illustrate a semiconductor device.

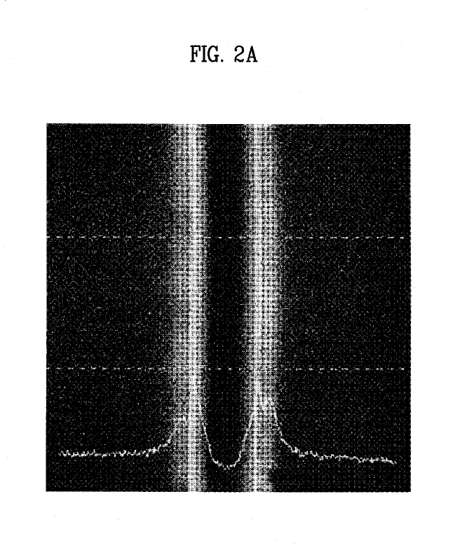

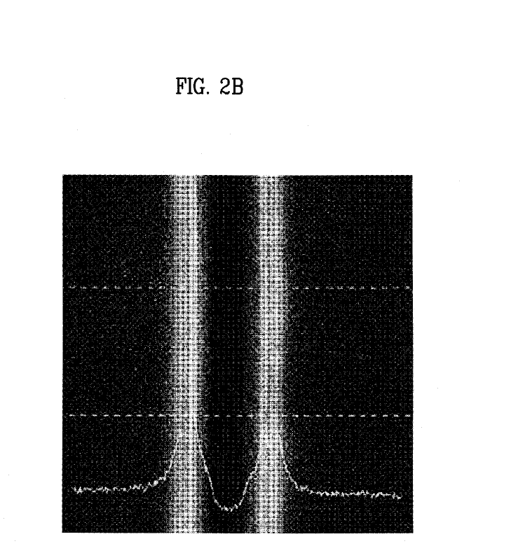

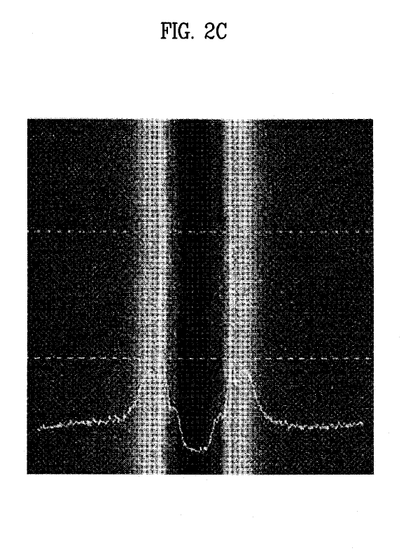

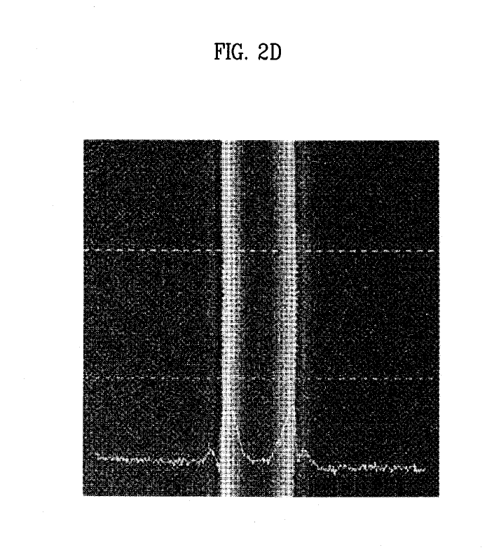

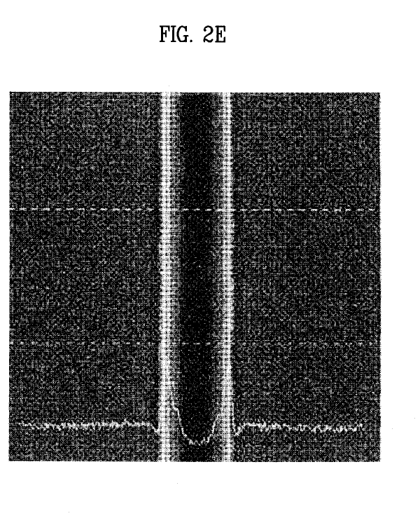

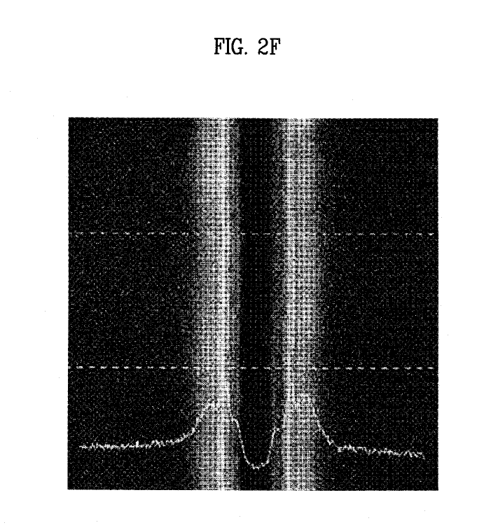

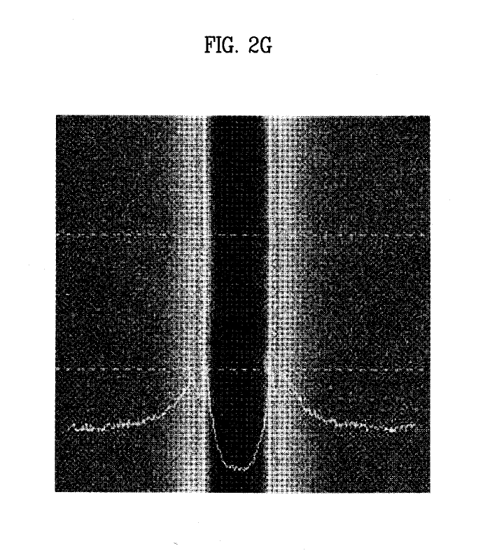

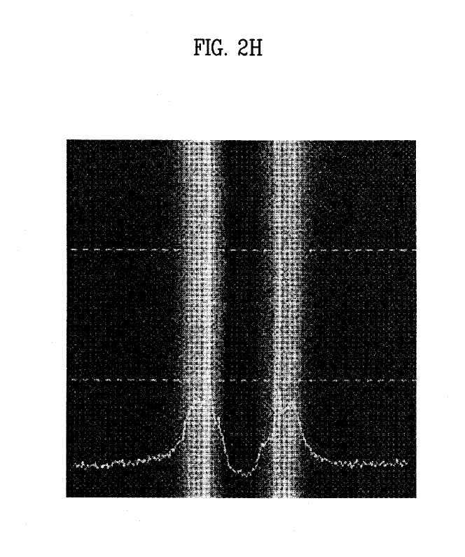

Example FIGS. 2A to 2I illustrate a semiconductor device, in accordance with embodiments.

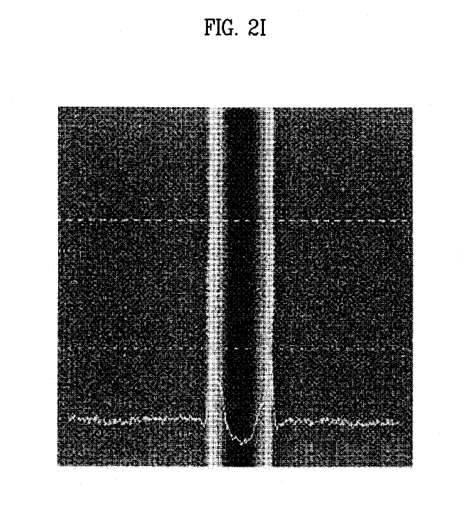

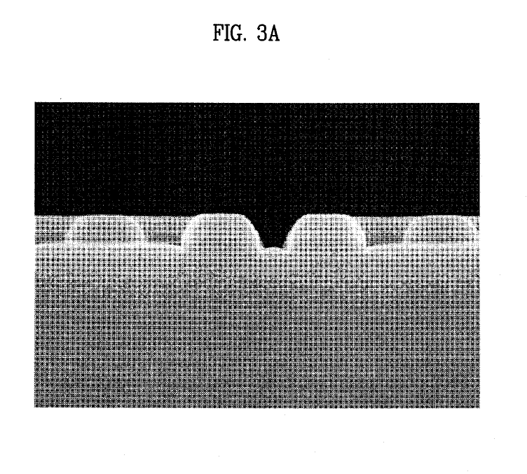

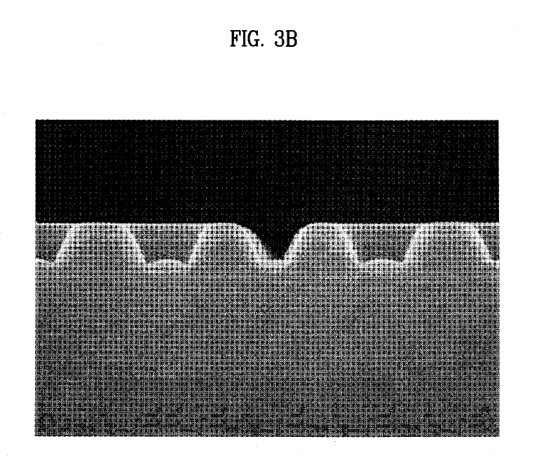

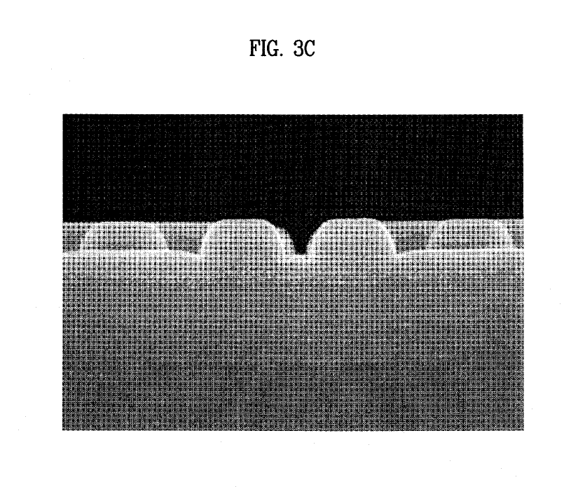

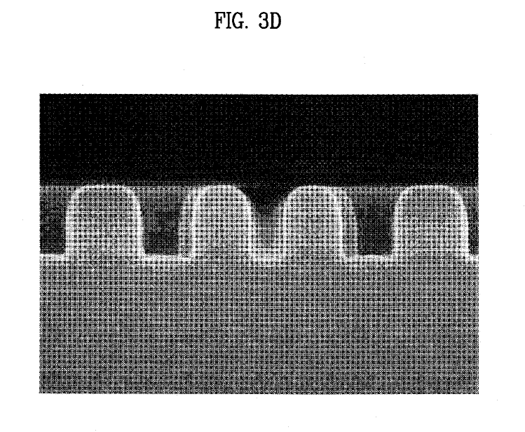

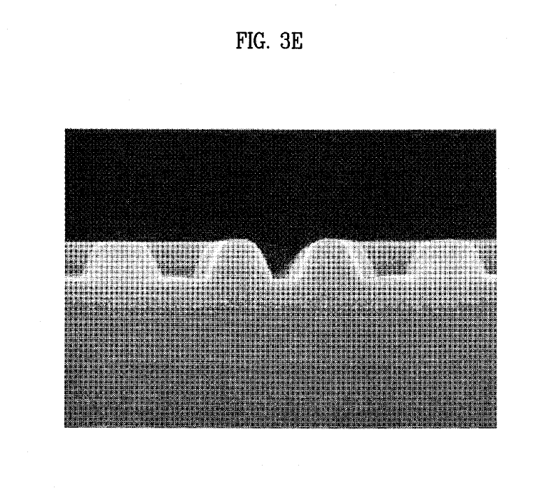

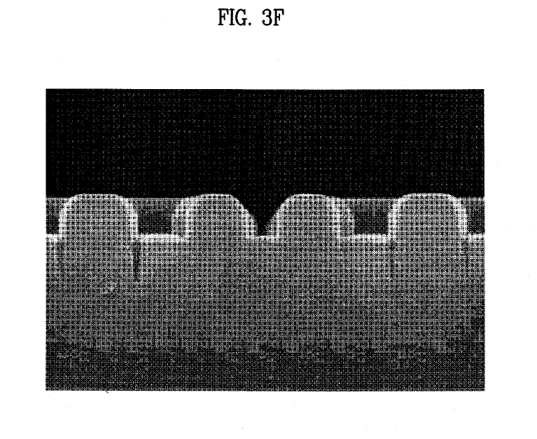

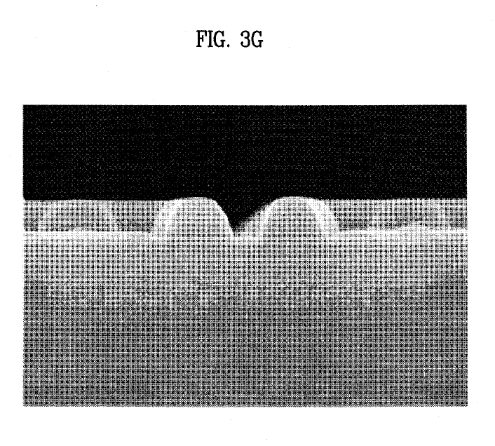

Example FIGS. 3A to 3H illustrate a semiconductor device, in accordance with embodiments.

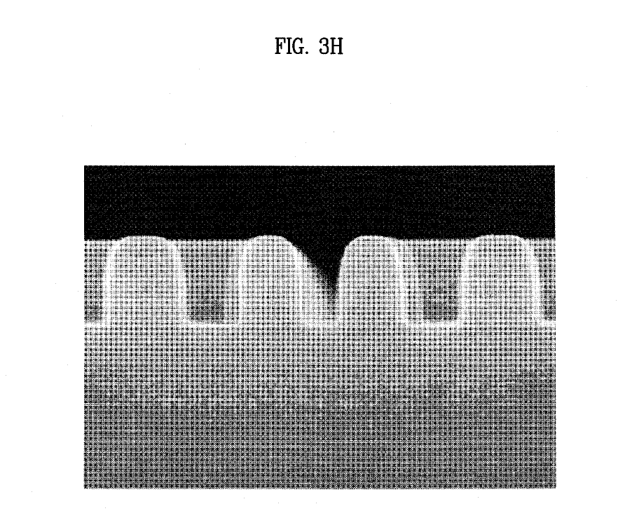

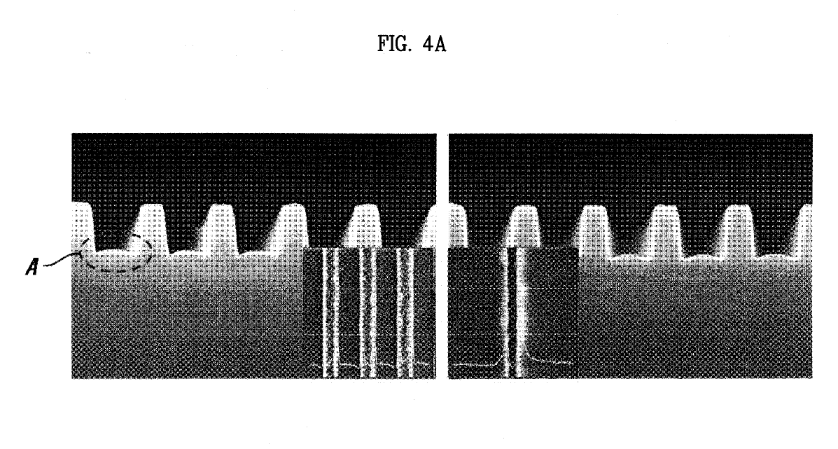

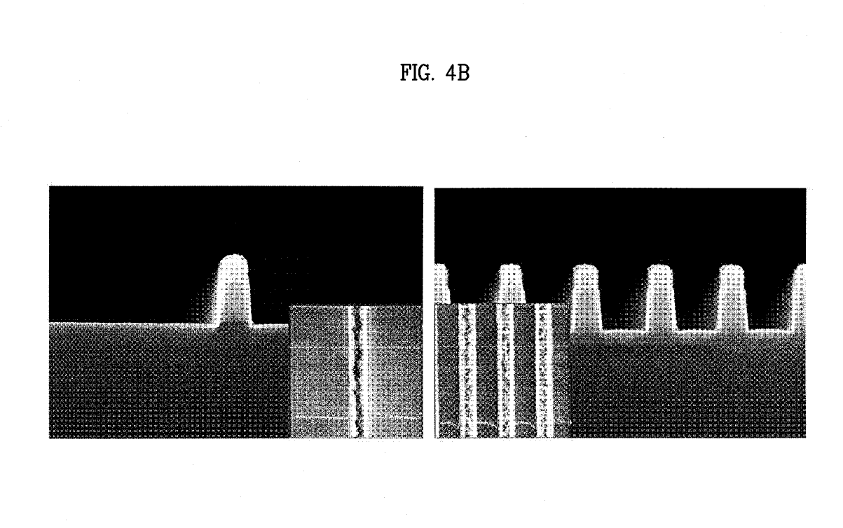

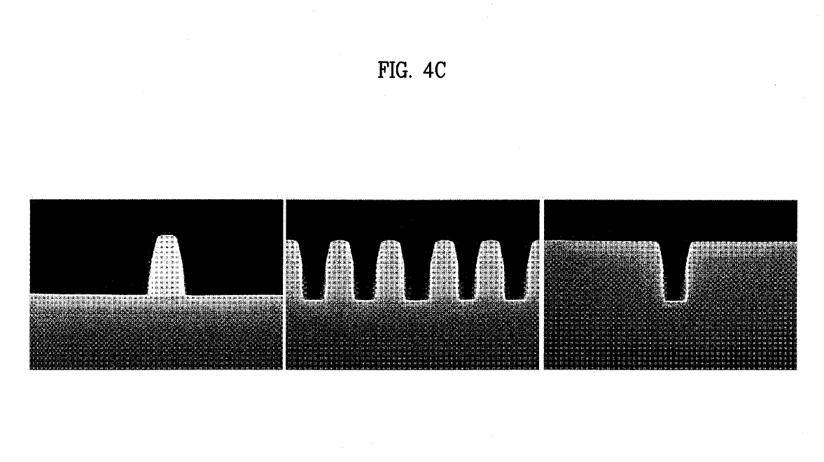

Example FIGS. 4A to 4C illustrate a method of manufacturing a semiconductor device, in accordance with embodiments.

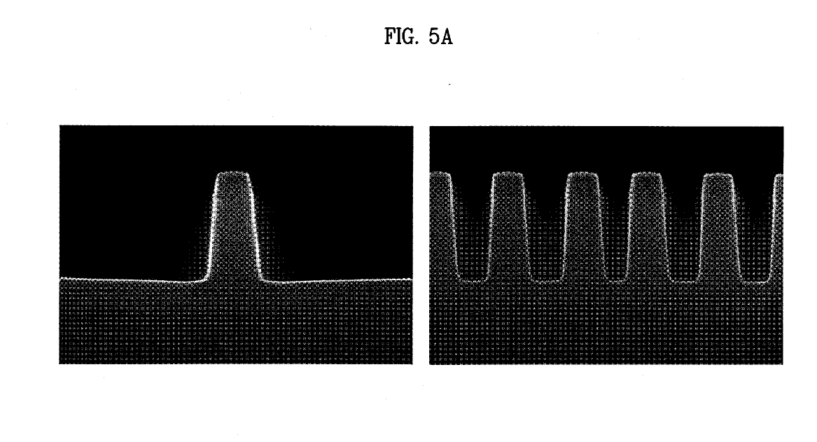

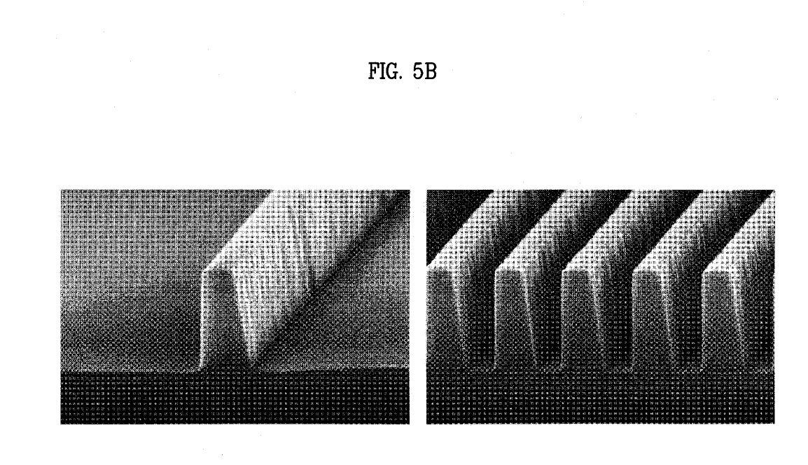

Example FIG. 5A to 5B illustrate a semiconductor device, in accordance with embodiments.

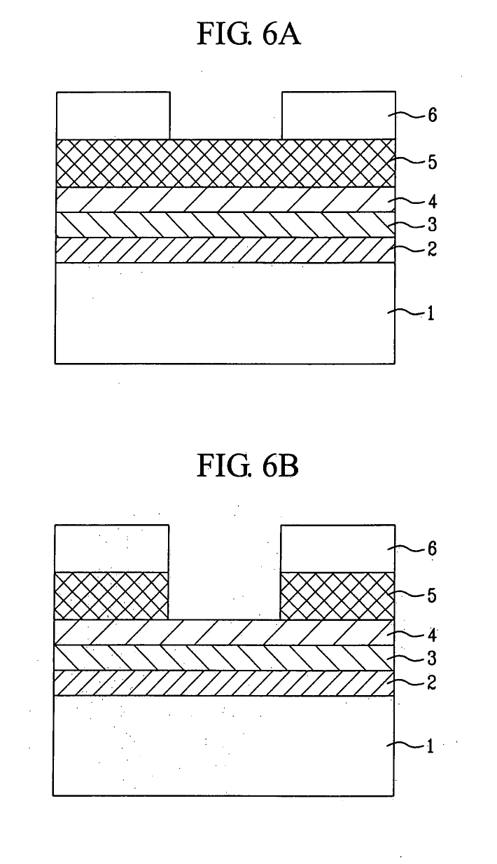

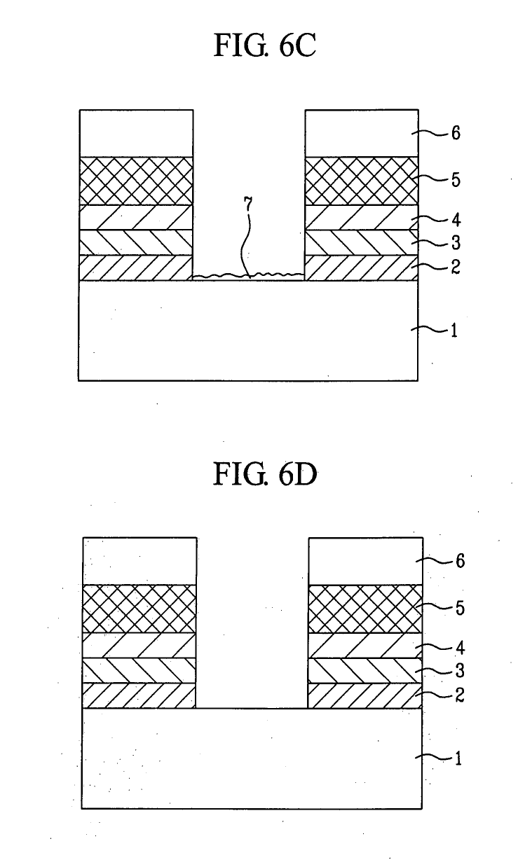

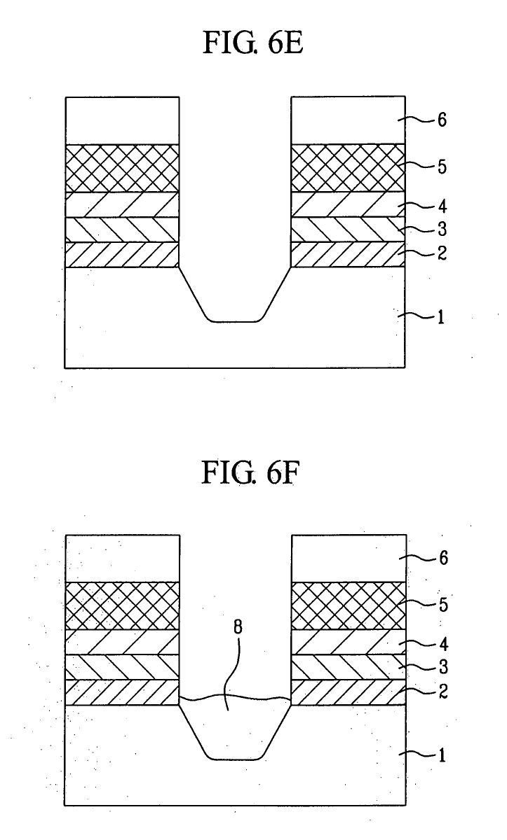

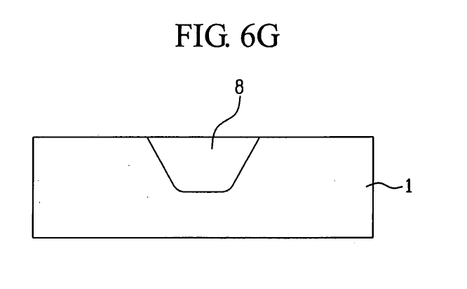

Example FIG. 6A to 6G illustrate a method of manufacturing a semiconductor device, in accordance with embodiments.

### DESCRIPTION

In embodiments, eliminating the problem of a reduction in thickness of a TEOS functioning as a mask for forming a STI, which is the most important problem when a 0.13 um FCT for a condition of 90 nm. Therefore, it can be important to delay the speed of the etching reaction, enhance the anisotropic etch ratio, and efficiently remove the reaction by-products. Such conditions are provided in Table 1.

Particularly, in order to delay the etching reaction speed, enhance the isotropic etching ratio, and efficiently remove reaction by-products, the AA spacer RIE conditions are different as described in the Table 1 to apply different conditions to each of nine sheets of a semiconductor substrate so that the AA spacer RIE etch is performed.

TABLE 1

| | | | | | | TEOS | |
|---|---|---|---|---|---|---|---|
| | | CD (nm) | | | | Thickness | |
| | Condition | IL | DL | IS | CL | (Å) | Whether or not |
| DOE | Tentative target | 147 | 140 | 112 | 147 | 525 | Badness |
| 1 | 35 mT/400 W/O2 37/CHF3 31/Ar 0 | 172 | 166 | 85 | 166 | 244.8 | Bad |
| 2 | 35 mT/600 W/O2 25/CHF3 50/Ar 100 | 191 | 181 | 65 | 184 | 342.5 | Bad |
| 3 | 35 mT/800 W/O2 18/CHF3 57/Ar 200 | 187 | 178 | 74 | 187 | 277.0 | Bad |
| 4 | 55 mT/400 W/O2 25/CHF3 50/Ar 200 | 183 | 174 | 79 | 175 | 263.5 | Good |
| 5 | 55 mT/600 W/O2 18/CHF3 57/Ar 0 | 167 | 159 | 93 | 161 | 149.5 | Good |
| 6 | 55 mT/800 W/O2 37/CHF3 37/Ar 100 | 194 | 169 | 81 | 172 | 307.0 | Bad |
| 7 | 75 mT/400 W/O2 18/CHF3 57/Ar 100 | 173 | 167 | 86 | 168 | 413.4 | Bad |
| 8 | 75 mT/600 W/O2 37/CHF3 37/Ar 200 | 184 | 173 | 80 | 74 | 398.5 | Bad |
| 9 | 75 mT/800 W/O2 25/CHF3 50/Ar 0 | 159 | 149 | 101 | 53 | 144.4 | Good |

As illustrated in example FIGS. 2A to 2I, in accordance with each condition described in Table 1, during performance of the AA spacer RIE process, as a result of the observation of a CD SEM image after performing the AA spacer RIE process, it was found that the best results were in conditions of a DOE 4, DOE 5, and DOE 9. These correspond to example FIGS. 2D, 2E, and 2I.

In accordance with embodiments, as the detailed conditions for setting the AA spacer RIE in a direction increasing the thickness of the TEOS remained by making the width of the isolation line small, the conditions can be set to be performed for 40 minutes using a pressure of 75 mT, power of 600 W, O₂ gas of 18 sccm, CHF₃ of 57 sccm, and Ar gas of 0 sccm.

In accordance with embodiments, in order to see the selectivity of oxide and poly in the AA SI RIE process, the experiment is progressed by fixing the etch time to 20 minutes and controlling the amount of power and gas as described in Table 2.

TABLE 2

| | | | | | | | | TEOS | | |
|---|---|---|---|---|---|---|---|---|---|---|
| | | Si Bot. CD (nm) | | | | | | Thickness | | |
| | Condition | IL | | | | | | (Å) | | |
| DOE | Tentative target | | D | DL | IS | DCL | LCL | 190 | D | Image |
| 1 | S 400 W/B 100 W/HBr 100/Cl2 10 | 180 | +8 | 171 | 80 | 173 | 177 | 441 | +195 | Bad |
| 2 | S 400 W/B 200 W/HBr 150/Cl2 20 | 210 | +19 | 199 | 60 | 200 | 202 | 146 | −197 | Bad |
| 3 | S 400 W/B 300 W/HBr 200/Cl2 30 | 200 | +13 | 187 | 72 | 190 | 193 | 217 | −70 | Bad |
| 4 | S 600 W/B 100 W/HBr 150/Cl2 30 | 192 | +9 | 183 | 69 | 185 | 188 | 251 | −13 | Bad |
| 5 | S 600 W/B 200 W/HBr 200/Cl2 10 | 186 | +21 | 168 | 86 | 172 | 175 | 31 | −119 | Good |
| 6 | S 600 W/B 300 W/HBr 100/Cl2 20 | 188 | −6 | 176 | 73 | 182 | 182 | 208 | −99 | Bad |
| 7 | S 800 W/B 100 W/HBr 200/Cl2 20 | 176 | +3 | 168 | 85 | 172 | 173 | 376 | −37 | Bad |
| 8 | S 800 W/B 200 W/HBr 100/Cl2 30 | 201 | +17 | 189 | 66 | 191 | 194 | 313 | −86 | Bad |
| 9 | S 800 W/B 300 W/HBr 150/Cl2 10 | 175 | +16 | 157 | 95 | 161 | 165 | 8 | −136 | Good |

As illustrated in example FIG. 3, showing the experimental result according to the conditions described in the Table 2, a DOE 4 and a DOE 8 corresponding to example FIGS. 2C and 2G, respectively, in the experimental result indicates the best results. However, since the problem that the gap between the line and the space is excessively narrow and the problem of the profile are involved, the alternative plan for improving this should be implemented.

In accordance with embodiments, the experiment is back progressed from the AA RIE based on the process in accordance with embodiments, whereby the stacked film includes a photoresist having a thickness of approximately 2.7 um, a BARC of 300 Å, the TEOS having a thickness of approximately 1000 Å, SiN having a thickness of approximately 1000 Å, and the gate oxide film having a thickness of approximately 45 Å. The etching is progressed for 50 seconds using an atmospheric pressure of 40 mT, a power of 600 W, O₂ gas of 10 sccm, Ar gas of 120 sccm, CF₄ of 40 sccm, and CHF₃ of 20 sccm.

As illustrated in FIG. 4A, after the AA RIE process is progressed, as a result of the observation of the cross section of the semiconductor device based on a cross SEM (XSEM), the remaining photo-resist appears 154 Å. Moreover, the generation of a dove-tail can be confirmed between the patterns. In the results of the experiment, the photoresist margin is small and the dove tail is generated so that the process condition is corrected back to progress the AA RIE process.

Accordingly, in the second experiment, the stacked film remains and the etch conditions are divided and progressed into the steps of the BARC, the RIE, the TEOS, the RIE, and the SIN RIE in performing a single existing etch process. Meanwhile, when etching the TEOS, the power may be increased from 120 W to 160 W, and Ar may be increased from 120 ccm to 160 ccm so that the condition is corrected and progressed in a direction improving the anisotropic etch ratio.

As illustrated in example FIG. 4B, when performing the AA RIE process in accordance with the corrected process condition, the photoresist margin of 945 Å including the BARC having a thickness of approximately 300 Å can be secured and the dove tail phenomenon can be solved.

The AA spacer RIE process can be removed and the process conditions can be set in a direction progressing the AA SI RIE process after the AA RIE process so that after the AA SI RIE process is progressed. As illustrated in example FIG. 4C, the TEOS can have a thickness of approximately 474 Å and a depth of 1797 Å.

Accordingly, the final etch condition determined by progressing the experiment for the 90 nm AA etch process is largely to secure the photo-resist margin and the thickness of the TESO in the three-step condition of the AA RIE, the AA spacer RIE, the AA SI RIE. Furthermore, in order to remove the dove tail, the etch condition can be set to progress by being divided into two-steps of the AA RIE and the AA SI RIE. Thereby, the final etch condition can be set as described in Table 3 regarding the condition of the AA RIE and Table 4 regarding the condition of the AA SI RIE.

TABLE 3

AA RIE condition

| Completion | bare RIE | Main etch |
|---|---|---|
| Step time (sec) | 10 | 45 |
| gap (mm) | 27 | 27 |
| pressure (mT) | 45 | 60 |
| RF power (Ws) | 600 | 600 |
| O2 (sccm) | 7 | 5 |
| Ar (sccm) | 120 | 160 |
| CF4 (sccm) | 40 | 80 |
| CHF3 (sccm) | 20 | 0 |
| Cooling | On | On |
| Edge He (Torr) | 40 | 40 |
| Center He (Torr) | 7 | 7 |

TABLE 4

AA SI RIE

| Completion | BT | Main etch |
|---|---|---|
| Step time (sec) | 10 | 62 |
| Pressure(mT) | 10 | 8 |
| SP(W) | 500 | 600 |
| BP(W) | 40 | 200 |
| HBr (sccm) | 0 | 150 |
| O2 (sccm) | 0 | 3 |
| CL2 (sccm) | 0 | 20 |
| CF4 (sccm) | 50 | 0 |

The AA RIE step is progressed by being divided into the BARC RIE process and the main etch process. And, the AA SI RIE progresses the experiment through the break through (BT) and the main etch processes. Each stacked film is measured at 1 nm by lowering the thickness of the TEOS from 1000 Å to 700 Å in the foregoing conditions while maintaining the other conditions.

As illustrated in example FIG. 5A, as a result of the progress of the experiment in accordance with the final conditions, the depth of the silicon substrate is 3150 Å and the thickness of the remaining TEOS is measured at approximately 250 Å. At this time, each of the CD is measured 140 nm and 121 nm. As illustrated in example FIG. 5B, it can be confirmed that the arrangement of the pattern provides a good result.

Accordingly, in the semiconductor device applied with 90 nm design rule the method for a trench etch process standardization in the active area can be proposed. In the 0.13 um FCT semiconductor device, the STI structure can be formed by conducting an etching process, which is subject to the AA RIE, the AA spacer RIE, and the AA SI RIE, a total of three times. However, in accordance with embodiments, an effective STI structure can be secured by performing the AA RIE and the AA SI RIE twice. Meaning, the AA spacer RIE process can be omitted so that the photolithographic process and the cleaning process can be reduced together. As a result, embodiments may have the advantage of reducing overall manufacturing cost and manufacturing length.

When the thickness of the TEOS serving as the hard mask for the deep trench etch compares with the 0.13 um FCT semiconductor device, embodiments can secure the TEOS with thicker thickness. And, the etch time and the source power can be controlled to obtain a depth of approximately 3500 Å, which is a target depth of the STI in the 90 nm semiconductor device. Thus, it can be possible to obtain a depth value in the range of approximately 3000 Å to 3800 Å.

As illustrated in example FIG. 6A, photoresist pattern 6 can be formed on and/or over semiconductor substrate 1 on and/or over which is sequentially formed an ONO structure including first oxide film 2, a nitride film 3 and second oxide film 4 and bottom anti-reflect coating (BARC) 5. First oxide film 2 may be composed of silicon oxide and second oxide film 4 may be composed of tetra ethyl ortho silicate (TEOS). Use of TEOS as second oxide film 4 can be advantageous since it has a better growth rate than a thermal oxide film (i.e., the silicon oxide film), and thus, can be thickly formed.

As illustrated in example FIG. 6B, a BARC RIE process can be performed using photoresist pattern 6 as an etch mask. Then, BARC 5 can be etched so that a portion of the uppermost surface of second oxide film 4 can be exposed.

As illustrated in example FIG. 6C, a main etching process on first oxide film 2, nitride film 3, and second oxide film 4, can then be performed using photoresist pattern 6 and BARC 5 as an etch mask, thereby exposing a portion of the uppermost surface of semiconductor substrate 1. Natural oxide film 7 can then be formed on and/or over exposed portion of semiconductor substrate 1.

As illustrated in example FIG. 6D, natural oxide film 7 is subsequently removed using a break through (BT) process to again re-expose the uppermost surface of substrate 1.

As illustrated in example FIG. 6E, a trench can be formed in the now exposed uppermost surface of substrate 1 by performing a main etching process. The trench can be formed at a depth of between approximately 3000 Å to 3800 Å.

As illustrated in example FIG. 6F, insulation material 8 such as an oxide film can be used to fill the trench.

As illustrated in example FIG. 6G, first oxide film 2, nitride film 3, second oxide film 4, BARC 5, and photoresist pattern 6 are subsequently removed, and insulation material 8 can be planarized to form a shallow trench isolation (STI). Insulation material 8 may be planarized using an etch-back process or chemical mechanical polishing (CMP).

In accordance with embodiments, a method of manufacturing a semiconductor device can secure an effective STI structure by twice performing AA RIE and the AA SI RIE, and when the thickness of the TEOS compares with the 0.13 um FCT semiconductor device, secure the TEOS that is thicker. A TEOS can be formed having a thickness of 3500 Å which is a target depth of the STI by controlling the etch time and the source power when manufacturing a 90 nm semiconductor device.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially forming a first oxide layer, a nitride layer, a second oxide layer, a bottom anti-reflect coating and a photo-resist pattern over a semiconductor substrate;
exposing the uppermost surface of the semiconductor substrate by performing a first reactive ion etch process; and then
forming a trench in the uppermost surface of the semiconductor substrate by performing a second reactive ion etch process.

2. The method of claim 1, wherein during exposing the uppermost surface of the semiconductor substrate at least a portion of the uppermost surface of the semiconductor substrate is exposed.

3. The method of claim 1, wherein the second oxide layer comprises tetra ethyl ortho silicate.

4. The method of claim 1, wherein the first reactive ion etch process comprises:
performing a bottom anti-reflect coating reactive ion etch process for exposing the uppermost surface of the second oxide layer by etching the bottom anti-reflect coating using the photo-resist pattern as an etch-mask; and
performing a main etch process for exposing a portion of the uppermost surface of the semiconductor substrate by etching the second oxide layer, the nitride layer and the first oxide layer using the photo-resist pattern and the bottom anti-reflect coating as etch masks.

5. The method of claim 1, wherein the main etch process comprises etching products of the semiconductor substrate corresponding to an active area.

6. The method of claim 1, wherein during exposing the uppermost surface of the semiconductor substrate a natural oxide layer is formed over the surface of the semiconductor substrate.

7. The method of claim 6, wherein the second reactive ion etch process comprises:
removing the natural oxide layer by performing a break through process; and
forming a trench in the semiconductor substrate from which the natural oxide layer is removed performing a main etch process.

8. The method of claim 1, wherein the trench is etched at a depth of between approximately 3000 Å to 3800 Å.

9. The method of claim 1, further comprising forming a shallow trench isolation by gap-filling insulation material in the trench.

10. The method of claim 9, wherein the insulation material comprises an oxide film.

11. A method comprising:
sequentially forming a silicon oxide film, a nitride film and a tetra ethyl ortho silicate film over a semiconductor substrate;
forming a bottom anti-reflect coating over the semiconductor substrate;
forming a photoresist pattern over the semiconductor substrate;
exposing a portion of the uppermost surface of the semiconductor substrate;
forming a trench at the exposed uppermost surface of the semiconductor substrate;
filling the trench with an insulation material; and then
forming a shallow trench isolation by planarizing the insulation material.

12. A method comprising:
forming an ONO structure over a semiconductor substrate including a first oxide film, a nitride film and a second oxide film;
forming a bottom anti-reflect coating over the semiconductor substrate;
forming a photoresist pattern over the semiconductor substrate;
performing a bottom anti-reflect coating reactive ion etch process using the photoresist pattern as an etch mask;
exposing a portion of the uppermost surface of the second oxide film by etching the bottom anti-reflect coating;
exposing a portion of the uppermost surface of the semiconductor substrate by performing a main etching process on the first oxide film, the nitride film, and the second oxide film using the photoresist pattern and the bottom anti-reflect coating as etch masks;
forming a natural oxide film over the exposed portion of the uppermost surface of the semiconductor substrate;
exposing the uppermost surface of substrate by removing the natural oxide film;
forming a trench at the exposed uppermost surface of the semiconductor substrate;
filling the trench with an insulation material;
removing the first oxide film, the nitride film, the second oxide film, the bottom anti-reflective coating and the photoresist pattern; and then
forming a shallow trench isolation by planarizing the insulation material.

13. The method of claim 12, wherein the first oxide film comprises silicon oxide and the second oxide film comprises tetra ethyl ortho silicate.

14. The method of claim 12, wherein the natural oxide film is removed using a break through process.

15. The method of claim 12, wherein the trench is formed in the semiconductor substrate by performing a main etching process.

16. The method of claim 15, wherein the trench is formed at a depth of between approximately 3000 Å to 3800 Å.

17. The method of claim 15, wherein the trench is formed at a depth of approximately 3500 Å.

18. The method of claim 12, wherein the insulation material comprises an oxide film.

19. The method of claim 12, wherein the insulation material is planarized using an etch-back process.

20. The method of claim 12, wherein the insulation material is planarized using chemical mechanical polishing.
